(19) United States
(12) Patent Application Publication
(10) Pub. No.: US 2007/0164310 A1
(43) Pub. Date: Jul. 19, 2007

(54) Electrostatic discharge element and diode having horizontal current paths, and method of manufacturing the same

(76) Inventor: Eun-Kyoung Kwon, Suwon-si (KR)

Correspondence Address: MILLS & ONELLO LLP, ELEVEN BEACON STREET, SUITE 605, BOSTON, MA, 02108, US

(21) Appl. No.: 11/654,755

(22) Filed: Jan. 18, 2007

(30) Foreign Application Priority Data
Jan. 18, 2006 (KR) 10-2006-0005456

(51) Int. Cl. H01L 29/74

(52) U.S. Cl. 257/173

(57) ABSTRACT

An electrostatic discharge element includes a first diode and a second diode. The first diode has a first well region formed in a substrate, a P-type ion-implanted region formed in the first well region, an N-type ion-implanted region formed in the first well region and spaced from the P-type ion-implanted region by a predetermined first distance, and a first intermediate layer formed on a portion of the first well region corresponding to the predetermined first distance. The second diode has a second well region form in the substrate, a P-type ion-implanted region formed in the second well region, an N-type ion-implanted region formed in the second well region and spaced from the P-type ion-implanted region by a predetermined second distance, and a second intermediate layer formed on a portion of the second well region corresponding to the predetermined second distance.

### CROSS-REFERENCE TO RELATED APPLICATION

This application claims priority under 35 U.S.C. §119 to Korean Patent Application No. 10-2006-0005456 filed on Jan. 18, 2006 in the Korean Intellectual Property Office, the disclosure of which is incorporated herein by reference in its entirety.

### BACKGROUND OF THE INVENTION

1. Field of the Invention

The present invention relates to an electrostatic discharge (ESD) device, and more particularly, to an electrostatic discharge element capable of reducing discharge resistance by isolating ion-implanted regions from each other to form horizontal current paths and a method of manufacturing the same.

2. Description of the Related Art

Since semiconductor devices operate at low voltage, the semiconductor devices can be vulnerable to static electricity when a relatively very high voltage or large charge is suddenly applied. In particular, as the size of high-integrated semiconductor devices is being decreased, the high-integrated semiconductor devices continue to be designed to operate at low voltage. Thus, the high-integrated semiconductor devices are vulnerable to the static electricity. As the semiconductor devices are integrated and designed to operate at low voltage, the problem of protecting the semiconductor device against the static electricity becomes critical. Accordingly, semiconductor devices generally include an electrostatic discharge element to protect against the static electricity.

The electrostatic discharge element should be able to absorb and discharge static electricity when a large charge is momentarily applied externally, without affecting its internal circuit. The electrostatic discharge element is designed using diodes or a CMOS structure. In this case, the electrostatic discharge element using diodes has a simple structure, in addition to excellent performance. The electrostatic discharge element using usual diodes is connected to an input/output node that transmits and receives electric signals to and from sources external to the semiconductor device. The electrostatic discharge element using diodes includes a diode connected between the input/output node and a power supply voltage node, and a diode connected between the input/output node and a ground voltage node. The diodes discharge a large charge momentarily applied externally through the power supply voltage node and the ground voltage node, without affecting its internal circuit. The diodes of the electrostatic discharge element are kept in a turn-off state during steady state. In contrast, when static electricity is generated, the diodes are turned on to discharge the static electricity. As the resistance between a P-type node and an N-type node is lowered during the turn-on state, the diodes can more effectively discharge static electricity.

However, there is no costumed process of manufacturing only an electrostatic discharge element, as the electrostatic discharge element is currently manufactured by using a process of manufacturing transistors. As a result, a conventional electrostatic discharge element includes an isolation region. Thus, discharge paths go around the isolation region. For this reason, it is difficult to sufficiently lower resistance between the nodes.

### SUMMARY OF THE INVENTION

In accordance with one aspect of the present invention, provided is an electrostatic discharge element that includes a first diode and a second diode. The first diode has a first well region formed in a substrate, a P-type ion-implanted region formed in the first well region, an N-type ion-implanted region formed in the first well region and spaced from the P-type ion-implanted region by a predetermined first distance, and a first intermediate layer formed on a portion of the first well region corresponding to the predetermined first distance. The second diode has a second well region form in the substrate, a P-type ion-implanted region formed in the second well region, an N-type ion-implanted region formed in the second well region and spaced from the P-type ion-implanted region by a predetermined second distance, and a second intermediate layer formed on a portion of the second well region corresponding to the predetermined second distance.

The first intermediate layer can include a first insulating layer and a first conductive layer and the second intermediate layer can include a second insulating layer and a second conductive layer.

Each of the first and the second insulating layers can comprise silicon oxide, and each of the first and the second conductive layers can comprise at least one of poly silicon, metal containing silicon, and metal.

The electrostatic discharge element can further include a ground voltage node electrically connected to the P-type ion-implanted region formed in the first well region, a power supply voltage node electrically connected to the N-type ion-implanted region formed in the second well region, and an input/output node electrically connected to the N-type ion-implanted region formed in the first well region and the P-type ion-implanted region formed in the second well region.

The first well region can be a P-type well region, and the second well region can be an N-type well region.

The electrostatic discharge element can further include a third intermediate layer formed between the first and second intermediate layers and between the P-type or N-type ion-implanted regions.

The electrostatic discharge element can further include an isolation region formed between the P-type or N-type ion-implanted regions.

In accordance with another aspect of the invention, provided is a method of manufacturing an electrostatic discharge element comprising forming a first well region in a substrate, forming a second well region in the substrate, forming an intermediate layer on the first and the second well regions, forming P-type ion-implanted regions in the first and the second well regions, and forming N-type ion-implanted regions in the first and the second well regions.

The first well region can be a P-type well region, and the second well region can be an N-type well region.

The intermediate layer can be formed by laminating together an insulating layer and a conductive layer.

The insulating layer can comprise silicon oxide, and the conductive layer can comprise at least one of poly silicon, metal containing silicon, and metal.

In accordance with another aspect of the invention, provided is a diode that includes a well region formed in a substrate, a P-type ion-implanted region formed in the well region, a N-type ion-implanted region formed in the well region and spaced from the P-type ion-implanted region by a predetermined distance, and a first intermediate layer formed on a portion of the well region corresponding to the predetermined distance between the P-type ion-implanted region and the N-type ion-implanted region.

A width of the first intermediate layer can be larger than the distance.

The diode can further include a second intermediate layer formed on the substrate with one of the P-type or N-type ion-implanted regions between the second intermediate layer and the first intermediate layer.

The diode can further include an isolation region formed between the P-type or N-type ion-implanted regions.

The diode can further include an isolation region formed in the substrate and configured to surround the P-type ion-implanted region, the N-type ion-implanted region, and the first intermediate layer in three or more directions.

In accordance with another aspect of the invention, provided is a diode that includes a well region formed in a substrate, a first ion-implanted region formed in the well region, a second ion-implanted region formed in the well region and spaced from the first ion-implanted region by a first distance in one direction, a third ion-implanted region formed in the well region and spaced from the first ion-implanted region by a second distance in another direction opposite to the one direction, a first insulating layer formed on a portion of the well region corresponding to the first distance, a first conductive layer formed on the first insulating layer, a second insulating layer formed on a portion of the well region corresponding to the second distance, and a second conductive layer formed on the second insulating layer.

In accordance with another aspect of the invention, provided is a diode that includes a well region formed in a substrate, a first ion-implanted region formed in the well region, an insulating layer formed in the well region and configured to surround the first ion-implanted region in three directions, a conductive layer formed on the insulating layer, and a second ion-implanted region formed in the well region and outside the insulating layer.

In accordance with another aspect of the invention, provided is a diode that includes a well region formed in a substrate, a first ion-implanted region formed in the well region, an insulating layer formed in the well region and configured to surround the first ion-implanted region in four directions, a conductive layer formed on the insulating layer, and a second ion-implanted region formed in the well region and outside the insulating layer.

In accordance with another aspect of the invention, provided is an electrostatic discharge element that includes a first diode and a second diode. The first diode has a P-type well region formed in a substrate, N-type ion-implanted regions formed in the P-type well region and spaced from each other by a predetermined first distance, a first intermediate layer formed on a portion of the well region corresponding to the predetermined first distance, and isolation regions formed outside the N-type ion-implanted regions. The second diode has a N-type well region formed in the P-type well region, P-type ion-implanted regions formed in the N-type well region and spaced from each other by a predetermined second distance, a second intermediate layer formed on portion of the well region corresponding to the predetermined second distance, and isolation regions formed outside the P-type ion-implanted regions.

### BRIEF DESCRIPTION OF THE DRAWINGS

Various aspects of the invention will become more apparent in view of the attached drawing figures, which are provided by way of example, not by way of limitation, wherein like elements are represented by like reference numerals, which are given by way of illustration only and thus do not limit the example embodiments of the present invention, in which:

FIGS. 1A and 1B are views schematically showing an embodiment of an electrostatic discharge element according to an aspect of the invention;

FIGS. 2A and 2B are cross-sectional views schematically showing various embodiments of diodes according to aspects of the invention;

FIGS. 3A to 3D are plan views schematically showing various embodiments of diodes according to aspects of the invention;

FIGS. 4B to 4E are plan views schematically showing various embodiments of diodes according to aspects of the invention;

FIGS. 5A to 5D are views illustrating an embodiment of a method of manufacturing an electrostatic discharge element according to aspects of the invention;

FIGS. 6A to 6E are views illustrating an embodiment of a method of manufacturing a diode according to aspects of the invention; and

FIG. 7 is a view schematically showing another embodiment of an electrostatic discharge element according to aspects of the invention.

### DESCRIPTION OF THE PREFERRED EMBODIMENTS

Advantages and features of the present invention can be understood more readily by reference to the following detailed description of preferred exemplary embodiments and the accompanying drawings. The present invention can, however, be embodied in many different forms and should not be construed as being limited to the embodiments set forth herein. In the drawings, the shape and thickness of layers and regions are exaggerated for clarity.

It will be understood that, although the terms first, second, etc. can be used herein to describe various elements, these elements should not be limited by these terms. These terms are used to distinguish one element from another. For example, a first element could be termed a second element, and, similarly, a second element could be termed a first element, without departing from the scope of the present invention. And, as used herein, the wording “and/or” includes each individual item listed and any combination of items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Preferred illustrative embodiments will be described below with reference to plan views and cross-sectional views, which are exemplary drawings of various aspects of the invention. The exemplary drawings cancan be modified by manufacturing techniques and/or tolerances. Accordingly, the preferred embodiments and the invention are not limited to specific configurations shown in the drawings, and include modifications based on manufacturing processes. Therefore, regions shown in the drawings have schematic characteristics. In addition, the shapes of the regions shown in the drawings exemplify specific shapes of regions in an element, and do not limit the invention, and the proportions of the regions can not be to scale.

In this specification, a P-type well cancan be defined as a P-type substrate. When the P-type substrate into which P-type impurities are doped is used, the P-type well can not be formed. Therefore, regions shown and described as P-type wells in this specification can be defined as a P-type substrate.

Further, although a P-type well region and an N-type well region described in this specification are spaced from each other, the P-type well region and the N-type well region can be not spaced from each other and one of them can include the other. That is, an N-type well region can be formed in a large P-type well region, and a P-type well region can be formed in a large N-type well region.

Hereinafter, the illustrative embodiments of various aspects of the invention will be described in detail with reference to accompanying drawings.

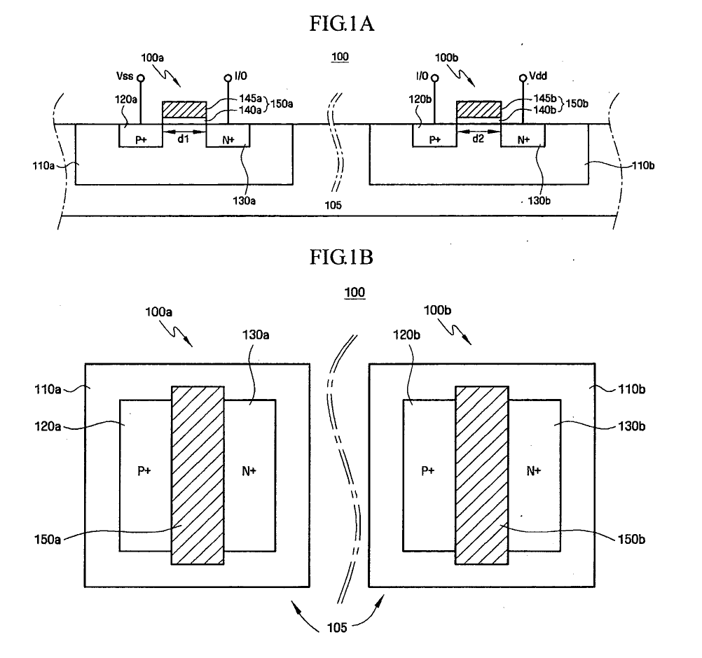

FIG. 1A is a schematic cross-sectional view of an electrostatic discharge element 100 according to an embodiment of the invention.

Referring to FIG. 1A, the electrostatic discharge element 100 according to the embodiment includes diodes 100a and 110b. The diode 100a includes a P-type well region 110a formed in a substrate 105, a P-type ion-implanted region 120a formed in the P-type well region 110a, an N-type ion-implanted region 130a that is formed in the P-type well region 110a and spaced from the P-type ion-implanted region 120a by a predetermined distance d1, and a first intermediate layer 150a formed on a portion of the P-type well region 110a corresponding to the predetermined distance d1. The diode 100b includes an N-type well region 110b formed in the substrate 105, a P-type ion-implanted region 120b formed in the N-type well region 110b, an N-type ion-implanted region 130b that is formed in the N-type well region 110b and spaced from the P-type ion-implanted region 120b by a predetermined distance d2, and a second intermediate layer 150b formed on a portion of the N-type well region 110b corresponding to the predetermined distance d2.

The substrate 105 is a semiconductor substrate, and can be a substrate into which P-type or N-type ions are implanted with a low concentration.

The P-type ions to be implanted into the substrate 105, the P-type well region 110a or the P-type ion-implanted regions 120a and 120b can be B (boron), as an example. In addition, the N-type ions to be implanted into the substrate 105, the N-type well region 110b or the N-type ion-implanted regions 130a and 130b can be P (Phosphorous) or As (Asenic), as examples.

The concentration of the ions implanted into the well regions 110a and 110b is higher than that of the ions to be implanted into the substrate 105, and the concentration of the ions implanted into the ion-implanted regions 120a, 120b, 130a, add 130b is higher than that of the ions to be implanted into the well regions 110a and 110b. One concentration of the ions can be in the range of 10 to 100 times of another concentration, and can be larger than the 100 times of another concentration. For example, the concentrations of the implanted ions can be changed depending on the operation voltages of semiconductor devices or the resistances between the ion-implanted regions. Since a specific concentration can be adjusted depending on a characteristic of each semiconductor device and is known in the art, the detailed description of the adjustment will be omitted.

The P-type ion-implanted regions 120a and 120b can be spaced from the N-type ion-implanted regions 130a and 130b by the predetermined distances d1 and d2, respectively.

The P-type ion-implanted regions 120a and 120b correspond to anodes of the diodes, and the N-type ion-implanted regions 130a and 130b correspond to cathodes of the diodes.

Each of the P-type ion-implanted regions 120a and 120b and the N-type ion-implanted regions 130a and 130b does not have an interruption region, such as the isolation region, and current horizontally flows in the ion-implanted regions. Accordingly, each of the ion-implanted regions has low resistance.

The intermediate layers 150a and 150b, which space the P-type ion-implanted regions 120a and 120b from the N-type ion-implanted regions 130a and 130b, are formed on the portions of the well regions corresponding to the predetermined distances d1 and d2 between the P-type ion-implanted regions 120a and 120b and the N-type ion-implanted regions 130a and 130b, respectively.

The first intermediate layer 150a includes a first insulating layer 140a and a first conductive layer 145a, and the second intermediate layer 150b includes a second insulating layer 140b and a second conductive layer 145b.

The first and second insulating layers 140a and 140b can be formed in the same process with the same material as a gate insulating film formed when a transistor is formed in a cell or transistor circuit region. Since the gate insulating film is usually made of silicon oxide, each of the first and second insulating layers 140a and 140b can be a silicon oxide layer.

The first and second conductive layers 145a and 145b can be also formed in the same process with the same material as a gate electrode formed when a transistor is formed in a cell or transistor circuit region. The gate electrode can be usually made of poly silicon, conductive material containing silicon (silicide material), and metal, or the gate electrode can be formed by a laminated structure made of a combination thereof. Accordingly, the first and second conductive layers 145a and 145b can also be made of poly silicon, conductive material containing silicon, and metal.

The reason why the same gate insulating film and gate electrode as those of the transistor in the cell or transistor circuit region are used as the insulating layers 140a and 140b and the conductive layers 145a and 145b, is that the processes of manufacturing the gate insulating films and gate electrodes can be compatible with each other. The processes of manufacturing the gate insulating films and gate electrodes will be described in detail in the descriptions of the process of manufacturing the electrostatic discharge element 100.

Referring to FIG. 1A, the widths of the intermediate layers 150a and 150b, and the distances d1 and d2 between the P-type ion-implanted regions 120a and 120b and the N-type ion-implanted regions 130a and 130b can be equal to each other. However, the widths of the intermediate layers 150a and 150b can be larger than the distances d1 and d2 between the P-type ion-implanted regions 120a and 120b and the N-type ion-implanted regions 130a and 130b, respectively. This is due to the following reason: P-type and N-type ions can be implanted into the ion-implanted regions, and the P-type and N-type ions implanted into the P-type and N-type ion-implanted regions 120a, 120b, 130a, and 130b can be then diffused or moved into the inside of the substrate 105 by a thermal treatment process.

In addition, although each of the regions (well regions and ion-implanted regions) is shown in a rectangular shape having corners, this is exemplarily shown so that the invention is more easily understood. Actually, each of the regions can be also formed in a round shape not having corners.

Each of the elements should be electrically connected to a power supply voltage node Vdd, a ground voltage node Vss, and an input/output node I/O to serve as an electrostatic discharge element. A cathode of a diode electrically connected between the power supply voltage node Vdd and the input/output node I/O can be electrically connected to the power supply voltage node Vdd, and an anode thereof can be electrically connected to the input/output node I/O. Since the voltage of the power supply voltage node Vdd is generally higher than that of the input/output node I/O, the diode can be reverse biased.

In addition, a cathode of a diode electrically connected between the input/output node I/O and the ground voltage node Vss can be electrically connected to the input/output node I/O, and an anode thereof can be electrically connected to the ground voltage node Vss. Since the voltage of the input/output node I/O is generally higher than that of the ground voltage node Vss, this diode can be also reverse biased. Since the diodes are reverse biased, current does not flow in a steady state.

If high voltage or large charge is applied to the diodes from an external source, the diodes are broken down. Accordingly, the high voltage or large charge is discharged from the power supply voltage node or ground voltage node.

Specifically, an electrostatic discharge element according to this embodiment will be described below with reference to FIG. 1A. The P-type ion-implanted region 120a formed in the P-type well region 110a can be electrically connected to the ground voltage node, and the N-type ion-implanted region 130a formed in the P-type well region 110a can be electrically connected to the input/output node. In addition, the N-type ion-implanted region 130b formed in the N-type well region 110b can be electrically connected to the power supply voltage node, and the P-type ion-implanted region 120b formed in the N-type well region 110b can be electrically connected to the input/output node. Diodes connected to the power supply voltage node Vdd, the ground voltage node Vss, and the input/output node I/O can serve as an electrostatic discharge element.

FIG. 1B is a plan view schematically showing an embodiment of the electrostatic discharge element 100, which is shown in FIG. 1A.

Referring to FIG. 1B, the electrostatic discharge element 100 includes the P-type well region 110a and the N-type well region 110b that are formed in the substrate 105, the P-type ion-implanted regions 120a and 120b and the N-type ion-implanted regions 130a and 130b that are spaced from each other in the P-type and N-type well regions 110a and 110b by the predetermined distances, and the intermediate layers 150a and 150b that are formed on respective portions of the well regions corresponding to the predetermined distances.

The P-type ion-implanted region 120a and the N-type ion-implanted regions 130a are formed in the well region 110a, and can be completely spaced from each other. In addition, the P-type ion-implanted region 120b and the N-type ion-implanted region 130b are formed in the well region 110b, and can be completely spaced from each other.

In FIG. 1B, each of the well regions 110a and 110b, the ion-implanted regions 120a, 120b, 130a, and 130b, and the intermediate layers 150a and 150b is shown in a rectangular shape having corners. However, each of the well regions, the ion-implanted regions, and the intermediate layers can be also formed in a round shape not having corners or in other shapes having rounded corners.

Further, in the electrostatic discharge element 100 according to the embodiment of the invention, the diodes 100a and 100b can be not divided from each other in the P-type well region 110a and the N-type well region 110b. The P-type well region 110a and the N-type well region 110b are merely shown for illustrative purposes to be compatible with the process of manufacturing a CMOS semiconductor device, and the well regions 110a and 110b are not necessarily limited to the P-type or N-type well regions. Therefore, all the well regions 110a and 110b can be P-type well regions, or can be N-type well regions.

Since FIG. 1B is a plan view, the insulating layers 140a and 140b are not shown.

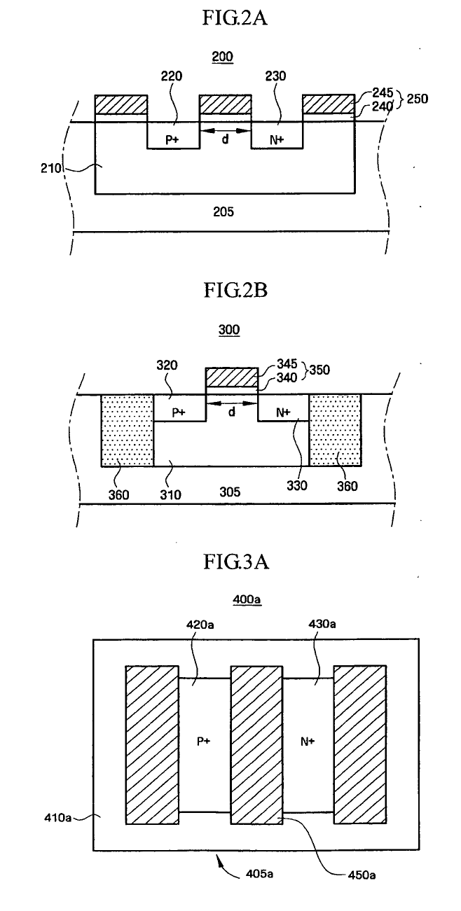

FIG. 2A is a cross-sectional view schematically showing a diode 200 according to another embodiment of the invention.

Referring to FIG. 2A, another embodiment of a diode 200 according to aspects of the invention includes a well region 210 formed in a substrate 205, P-type and N-type ion-implanted regions 220 and 230 spaced from each other in the well region 210 by a predetermined distance d, and an intermediate layer 250 formed on a portion of the well region corresponding to the predetermined distance d and on portions of the well region 210 outside of the ion-implanted regions 220 and 230. The well region 210 can be a P-type or an N-type well region.

The intermediate layer 250 can comprise an insulating layer 240 and a conductive layer 245, which can be formed to define the ion-implanted regions 220 and 230. In FIG. 2A, each of the widths of the ion-implanted regions 220 and 230, and the distance d in the intermediate layer 250 are equal to each other. However, after ions are implanted into the ion-implanted regions 220 and 230, a thermal treatment process can be performed. Accordingly, each of the widths of the ion-implanted regions 220 and 230 can be larger than the distance d in the intermediate layer 250.

FIG. 2B is a cross-sectional view schematically showing a diode 300 according to another embodiment of the invention.

Referring to FIG. 2B, another embodiment of a diode 300 according to aspects of the invention includes a well region 310 formed in a substrate 305, P-type and N-type ion-implanted regions 320 and 330 spaced from each other in the well region 310 by a predetermined distance d, an intermediate layer 350 formed on a portion of the well region corresponding to the predetermined distance d, and isolation regions 360 formed outside the ion-implanted regions 320 and 330 in the substrate 305.

The isolation regions 360 can increase resistance to reduce leakage current, so that current or charge flowing into and out of the ion-implanted regions 320 and 330 is not leaked externally.

In FIG. 2B, the isolation regions 360 are adjacent to the ion-implanted regions 320 and 330 and the well region 310. However, the isolation regions, the ion-implanted regions, and the well region are not necessarily adjacent to each other. The isolation regions 360 can be spaced from the ion-implanted regions 320 and 330. In addition, the isolation regions 360 can be formed in the well region 310, or can be formed outside of the well region 310and spaced from the well region 310. Further, although each of the isolation regions 360 has the same thickness as the well region 310 in FIG. 2B, each of the isolation regions 360 do not necessarily have the same thickness as the well region 310. In various embodiments, each of the isolation regions can be have a smaller thickness than the well region 310. Alternatively, each of the isolation regions can have a larger thickness than the well region 310, to further reduce leakage current and to improve the operational stability of the diode and device to which it belongs.

As an example, each of the thicknesses of the isolation regions 360 can be the same as that of the isolation region formed in a cell or transistor circuit.

The well region 310 can be a P-type or an N-type well region.

The intermediate layer 350 includes an insulating layer 340 and a conductive layer 345.

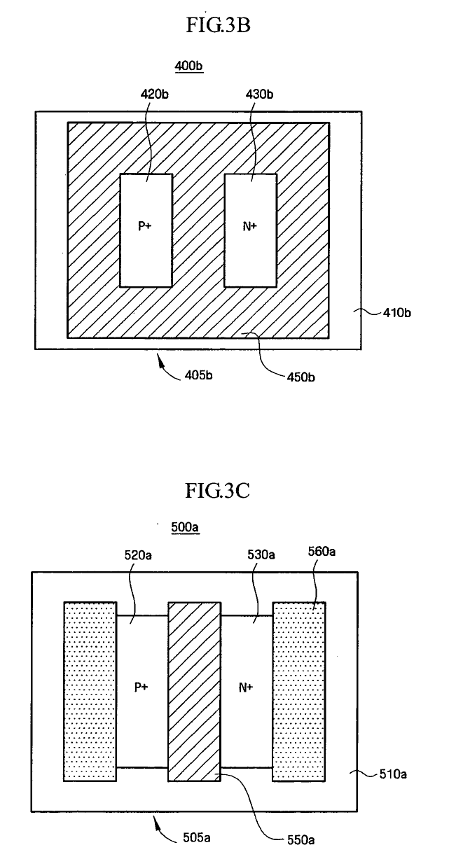

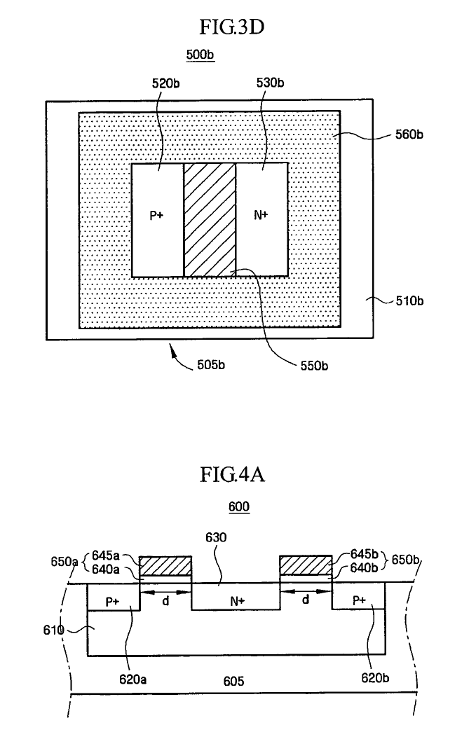

FIG. 3A is a plan view schematically showing another embodiment of a diode 400a according to aspects of the invention.

Referring to FIG. 3A, the diode 400a includes a well region 410a formed in a substrate 405a, P-type and N-type ion-implanted regions 420a and 430a spaced from each other in the well region 410a by a predetermined distance, and an intermediate layer 450a formed on both portions of the ion-implanted regions 420a and 430a. The intermediate layer 450a can be formed to define the ion-implanted regions 420a and 430a.

In FIG. 3A, each of the widths of the ion-implanted regions 420a and 430a, and the predetermined distance in the intermediate layer 450a are equal to each other. However, after ions are implanted into the ion-implanted regions 420a and 430a, a thermal treatment process is performed. Accordingly, each of the widths of the ion-implanted regions 420a and 430a can be larger than the predetermined distance in the intermediate layer 450a.

The well region 410a can be a P-type or an N-type well region.

FIG. 3B is a plan view schematically showing another embodiment of a diode 400b according to aspects of the invention.

Referring to FIG. 3B, the diode 400b includes a well region 410b formed in a substrate 405b, P-type and N-type ion-implanted regions 420b and 430b spaced from each other in the well region 410b by a predetermined distance, and an intermediate layer 450b that is formed to surround a portion of the well region corresponding to the predetermined distance and the ion-implanted regions 420b and 430b.

In the diode 400b according to another embodiment of the invention, the intermediate layer 450b is formed to surround the ion-implanted regions 420b and 430b. Accordingly, it is advantageous to reduce the leakage current, and it is possible to define the ion-implanted regions 420b and 430b.

The well region 410b can be a P-type or an N-type well region.

FIG. 3C is a plan view schematically showing another embodiment of a diode 500a according to of the invention.

Referring to FIG. 3C, the diode 500a includes a well region 510a formed in a substrate 505a, P-type and N-type ion-implanted regions 520a and 530a spaced from each other in the well region 510a by a predetermined distance, an intermediate layer 550a formed on a portion of the well region corresponding to the predetermined distance, and isolation regions 560a formed outside the ion-implanted regions 520a and 530a formed in the substrate 505.

The isolation regions 560a increase resistance to reduce leakage current, so that current or charge flowing into and out of the ion-implanted regions 520a and 530a is not leaked to the outside.

In FIG. 3C, the isolation regions 560a are adjacent to the ion-implanted regions 520a and 530a. However, the isolation regions and the ion-implanted regions are not necessarily adjacent to each other. The isolation regions 560a can be spaced from the ion-implanted regions 520a and 530a.

Furthermore, in FIG. 3C, the isolation regions 560a are included in the well region 510a. However, the isolation regions 560a are not necessarily included in the well region 510a, and can be formed outside of the well region 510a and spaced from the well region 510a.

Each of the widths of the isolation regions 560a can be the same as that of the isolation region formed in a cell or transistor circuit region.

The well region 510a can be a P-type or an N-type well region.

FIG. 3D is a plan view schematically showing another embodiment of a diode 500b according to aspects of the invention.

Referring to FIG. 3D, the diode 500b includes a well region 510b formed in a substrate 505b, P-type and N-type ion-implanted regions 520b and 530b spaced from each other in the well region 5 10b by a predetermined distance, an intermediate layer 550b formed on a portion of the well region corresponding to the predetermined distance, and isolation regions 560b that are formed in the well region 510b and surround the ion-implanted regions 520b and 530b.

Since the isolation regions 560b completely surround the ion-implanted regions 520b and 530b, the diode 500b has a significantly improved effect on the reduction of the leakage current among the diodes according to the embodiments of the invention.

The well region 510b can be a P-type or an N-type well region.

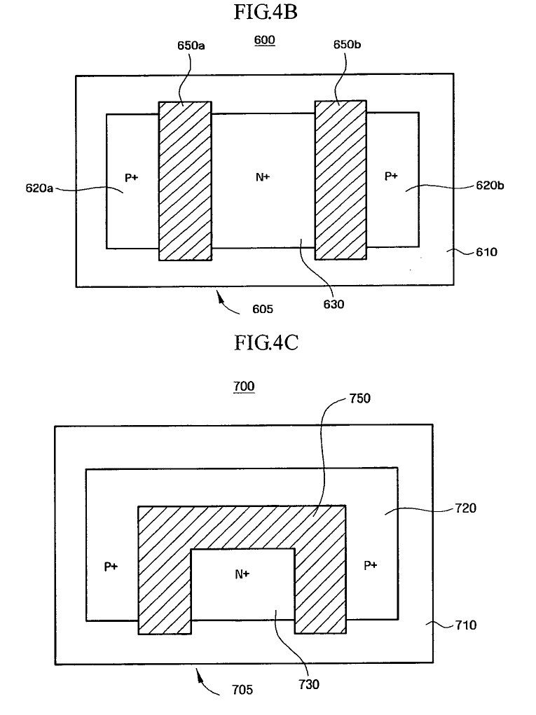

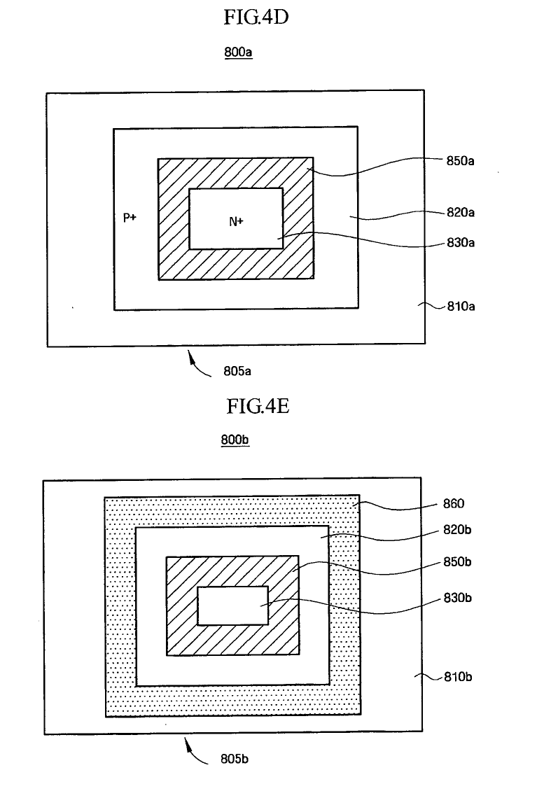

FIG. 4A is a cross-sectional view schematically showing another embodiment of a diode 600 according to aspects of the invention.

Referring to FIG. 4A, the diode 600 includes a well region 610 formed in a substrate 605, an N-type ion-implanted region 630 formed in the well region 610, P-type ion-implanted regions 620a and 620b spaced from the N-type ion-implanted region 630 in opposite directions by predetermined distances, and intermediate layers 650a and 650b formed on respective portions of the well region corresponding to the predetermined distances.

The well region 610 can be a P-type or an N-type well region.

The intermediate layers 650a and 650b include insulating layers 640a and 640b, and conductive layers 650a and 650b, respectively. And the intermediate layers 650a and 650b can be formed to define ion-implanted regions 620a, 620b, and 630.

In FIG. 4A, each of the widths of the ion-implanted regions 620a and 620b, and the predetermined distances in the intermediate layers 650a and 650b are equal to each other. However, each of the widths of the ion-implanted regions 620a and 620b can be larger than the predetermined distances in the intermediate layers 650a and 650b, in other embodiments.

Since the diode 600 shown in FIG. 4A can include a plurality of current paths, it can provide a substantial improvement in electrostatic discharge.

The well region 610 of the diode 600 shown in FIG. 4A can be a P-type or an N-type well region, and the N-type ion-implanted region 630 and the P-type ion-implanted regions 620a and 620b can alternatively be formed as a P-type ion implantation region and an N-type ion-implantation region, respectively.

FIG. 4B is a plan view schematically showing an embodiment of the diode 600 of FIG. 4A.

Referring to FIG. 4B, the diode 600 includes the well region 610 formed in the substrate 605, the N-type ion-implanted region 630 formed in the well region 610, the P-type ion-implanted regions 620a and 620b spaced from the N-type ion-implanted region 630 in opposite directions by predetermined distances, and intermediate layers 650a and 650b formed on respective portions of the well region corresponding to the predetermined distances.

The well region 610 can be a P-type or an N-type well region.

The intermediate layers 650a and 650b can be formed to define the ion-implanted regions 620a, 620b, and 630.

Since the diode 600 shown in FIG. 4B can include a plurality of current paths, it can provide a substantial improvement in electrostatic discharge.

The well region 610 of the diode 600 shown in FIG. 4B can be a P-type or an N-type well region, and the N-type ion-implanted region 630 and the P-type ion-implanted regions 620a and 620b can alternatively be formed as a P-type ion implantation region and an N-type ion-implantation region, respectively.

FIG. 4C is a plan view schematically showing an embodiment of a diode according to aspects of the invention.

Referring to FIG. 4C, the diode 700 includes a well region 710 formed in a substrate 705, an N-type ion-implanted region 730 formed in the well region 710, an intermediate layer 750 surrounding the N-type ion-implanted region in three directions, and a P-type ion-implanted region 720 spaced from the N-type ion-implanted region 730 with the intermediate layer 750 therebetween.

Since the diode shown in FIG. 4C includes current paths of the P-type ion-implanted region 720 and the N-type ion-implanted region 730 in three directions, it can provide substantial improvement in electrostatic discharge than when the diode includes current paths in two directions.

The well region of the diode 700 shown in FIG. 4C can be a P-type or an N-type well region, and the N-type ion-implanted region 730 and the P-type ion-implanted region 720 can alternatively be formed as a P-type ion implantation region and an N-type ion-implantation region, respectively.

FIG. 4D is a plan view schematically showing another embodiment of a diode 800a according to aspects of the invention.

Referring to FIG. 4D, the diode 800a includes a well region 810a formed in a substrate 805a, an N-type ion-implanted region 830a formed in the well region 810a, a P-type ion-implanted region 820a that completely surrounds the N-type ion-implanted region 830a in four directions and is spaced from the N-type ion-implanted region 830a by a predetermined distance, and an intermediate layer 850a that is formed on a portion of the well region corresponding to the predetermined distance to completely surround the N-type ion-implanted region 830a in four directions.

Since the diode 800a shown in FIG. 4D includes current paths in three directions, the diode 800a has significantly improved performance in the electrostatic discharge, which can be better than that of the other diode embodiments above.

The well region 810a of the diode 800a shown in FIG. 4D can be a P-type or an N-type well region, and the N-type ion-implanted region 830a and the P-type ion-implanted region 820a can alternatively be formed as a P-type ion implantation region and an N-type ion-implantation region, respectively.

In FIG. 4D, each of the well region 810a, the N-type and P-type ion-implanted regions 820a and 830a, and the intermediate layer 850a is shown has having a rectangular shape. However, each of the well region, the N-type and P-type ion-implanted regions, and the intermediate layer can be also formed in a circular shape or in a shape having rounded corners, as examples.

FIG. 4E is a plan view schematically showing an embodiment of a diode 800b according to aspects of the invention.

Referring to FIG. 4E, the diode 800b includes a well region 810b formed in a substrate 805b, an N-type ion-implanted region 830b formed in the well region 810b, a P-type ion-implanted region 820b that completely surrounds the N-type ion-implanted region 830b in four directions and is spaced from the N-type ion-implanted region 830b by a predetermined distance, an intermediate layer 850b that is formed on a portion of the well region corresponding to the predetermined distance to completely surround the N-type ion-implanted region 830b in four directions, and an isolation region 860 completely surrounding the P-type ion-implanted region 820b in four directions.

Since the isolation region 860 surrounds the ion-implanted regions 820b and 830b, the diode 800b shown in FIG. 4E has the least leakage current among the above diode embodiments.

The well region 810b of the diode 800b shown in FIG. 4E can be a P-type or an N-type well region, and the N-type ion-implanted region 830b and the P-type ion-implanted region 820b can alternatively be formed as a P-type ion implantation region and an N-type ion-implantation region, respectively.

In FIG. 4E, each of the well region 810b, the N-type and P-type ion-implanted regions 820b and 830b, the intermediate layer 850b, and the isolation region 860 is shown as having a rectangular shape. However, each of the well region, the N-type and P-type ion-implanted regions, the intermediate layer, and the isolation region can be also formed in a circular shape or in a shape having rounded corners, as examples.

Subsequently, an embodiment of a method of manufacturing an electrostatic discharge element according to aspects of the invention will be described.

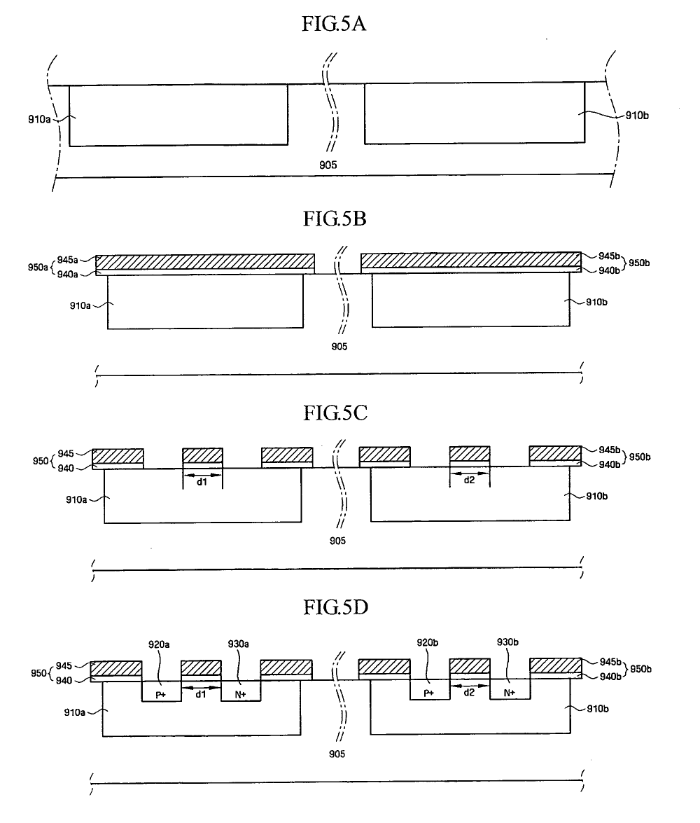

FIGS. 5A to 5D are views illustrating a method of manufacturing an electrostatic discharge element according to an embodiment of the invention.

The method of manufacturing the electrostatic discharge element shown in FIGS. 5A to 5D can be performed simultaneously with a process of forming a gate in a cell or transistor circuit region.

Referring to FIG. 5A, in this embodiment of a method of making the electrostatic discharge element, P-type and N-type well regions 910a and 910b are formed in a substrate 905.

A photoresist film is formed on the substrate 905 and then patterned to form a photoresist pattern exposing regions to be formed as a P-type or an N-type well region. Subsequently, ion-implantation is performed to form P-type and N-type well regions 910a and 910b. The process of forming the well regions 910a and 910b can be performed simultaneously with a process of forming a CMOS device in a cell or transistor region of the semiconductor, for example.

A process of implanting P-type ions and a process of implanting N-type ions can be separately performed. Accordingly, a process of forming the photoresist pattern, which exposes regions to be formed as a P-type or an N-type well region, is performed two or more times.

Alternatively, other films can be used to expose the regions to be formed as the well regions, i.e., other than the photoresist pattern. For example, silicon oxide or silicon nitride can be used to expose the regions to be formed as the well regions. For the purposes of this embodiment, a pattern exposing the regions to be formed as the well regions will be a photoresist pattern.

Subsequently, referring to FIG. 5B, an insulating layer 940a and a conductive layer 945a that are used to form intermediate layer 950a and an insulating layer 940b and a conductive layer 945b that are used to form an intermediate layer 950b are formed on the substrate on which the well regions are formed. Although being patterned in FIG. 5B, the insulating layers 940a and 940b and the conductive layers 945a and 945b can be not patterned, but rather could be formed on the entire surface of the substrate.

Referring to FIG. 5C, the insulating layers 940a and 940b and the conductive layers 945a and 945b are patterned to form the intermediate layers 950a and 950b, respectively.

A process of forming the intermediate layers 950a and 950b can be performed simultaneously with a process of patterning a gate in a cell or transistor circuit region, for example. That is, when a gate-insulating layer is formed in the cell or transistor circuit region, the insulating layers 940a and 940b can also be formed. In addition, when a gate electrode is formed in the cell or transistor circuit region, the conductive layers 945a and 945b can also be formed. Further, when a gate is patterned in the cell or transistor circuit region, the intermediate layers 950a and 950b can also be patterned.

Subsequently, referring to FIG. 5D, ions are implanted into the well regions 910a and 910b, which are formed in the substrate 905 exposed by the intermediate layers 950a and 950b, to form P-type ion-implanted regions 920a and 920b and N-type ion-implanted regions 930a and 930b.

After the process of FIG. 5D, the intermediate layers 950a and 950b are selectively removed to complete the electrostatic discharge element according to this embodiment.

FIGS. 5A to 5D, therefore, provide a method of manufacturing a electrostatic discharge element according to various aspects of the invention, including the formation of the intermediate layer or layers. The shape and size of the intermediate layers 950a and 950b, and the method of forming the intermediate layers 950a and 950b using a plurality of layers, can be modified within the scope of the invention.

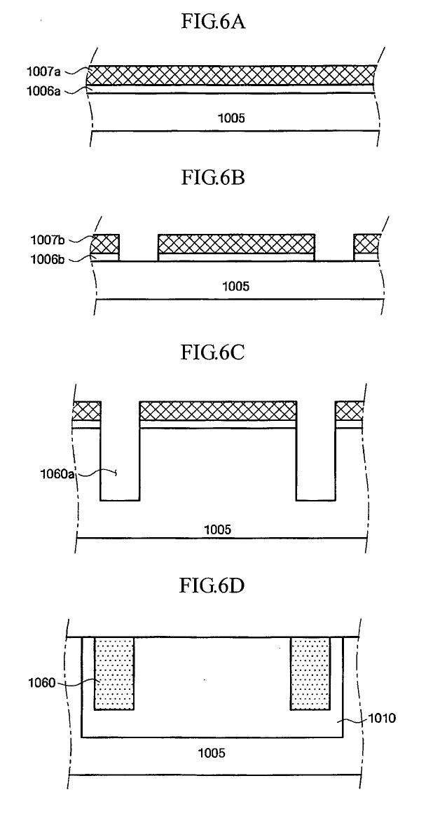

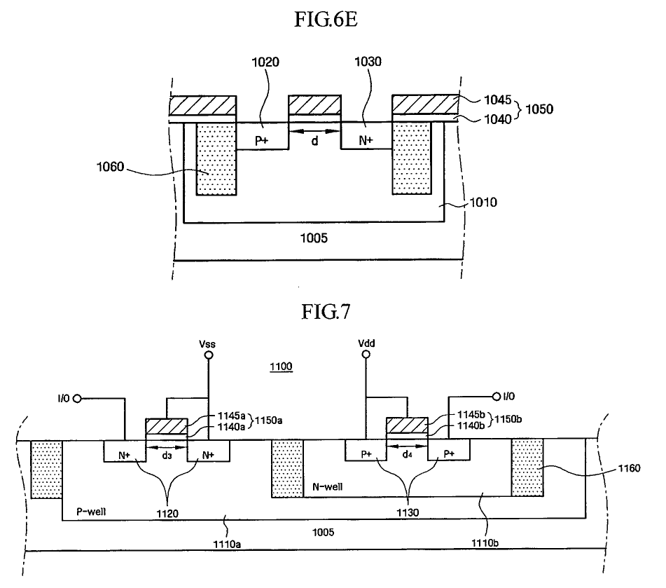

FIGS. 6A to 6E are views illustrating an embodiment of a method of manufacturing a diode according to aspects of the invention.

The method of manufacturing the diode shown in FIGS. 6A to 6E can be performed simultaneously with a process of forming an isolation region in a cell or transistor circuit region, as examples.

Referring to FIG. 6A, a buffer film 1006a and an etching prevention film 1007a are formed on a substrate 1005.

Each of the buffer film 1006a and the etching prevention film 1007a serves as an insulating film, and can be made of silicon oxide or silicon nitride, as examples.

Referring to FIG. 6B, the buffer film 1006a and the etching prevention film 1007a are patterned to selectively expose the upper surface of the substrate 1005.

In a process of selectively exposing the upper surface of the substrate 1005, a photoresist film is formed on the etching prevention film 1007a and then patterned to form a photoresist pattern exposing the upper surface of the etching prevention film 1007a. Next, the exposed portions of the etching prevention film 1007a and the buffer film 1006a are successively etched, and the photoresist pattern is removed to form a buffer pattern 1006b and an etching prevention film pattern 1007b.

Referring to FIG. 6C, the exposed substrate is etched to form trenches 1060a.

Referring to FIG. 6D, after the etching prevention film pattern 1007b and the buffer film pattern 1006b are removed to expose the entire surface of the substrate, the trenches 1060a are filled with an insulating material for isolating elements to form isolation regions 1060.

Next, ions are implanted into the substrate 1005 to form a well region 1010.

The insulating material for isolating elements can be silicon oxide, for example. Alternatively, the insulating material for isolating elements can be silicon nitride, as another example and can be selectively formed on the bottoms and sidewalls of the trenches 1060a, and can be filled into the trenches 1060a.

After the trenches 1060a are filled with the insulating material, a planarization process is performed to planarize the upper portions of the substrate 1005 and the isolation region 1060.

The well region 1010 can be formed by forming the isolation regions 1060, defining the regions into which ions are implanted by photoresist, performing a process of implanting ions, and removing the photoresist.

The well region 1010 can be wider than each of the isolation regions 1060.

A process of forming the region 1010 can be performed after a process of forming the isolation regions 1060.

Referring to FIG. 6E, an intermediate layer 1050 that includes an insulating layer 1040 and a conductive layer 1045 is formed in the substrate 1005 in which the isolation regions 1060 and the well region 1010 are formed, as previously described with respect to FIGS. 5B and 5C, for example. Subsequently, a process of implanting ions is performed to form the ion-implanted regions 1020 and 1030 between the portions of the intermediate layer 1050.

Finally, the intermediate layers 1050 are selectively removed to complete the diode according to the embodiment of the invention.

FIGS. 6A to 6E provide, therefore, an exemplified method of manufacturing a diode in accordance with aspects of the invention. The method of forming the shape and size of the isolation region 1060, and a method of the isolation region 1060 using a plurality of layers can be modified within the scope of the invention.

FIG. 7 is a cross-sectional view schematically showing another embodiment of an electrostatic discharge element according to aspects of the invention.

More specifically, the electrostatic discharge element is an electrostatic discharge element 1100 manufactured using a method of manufacturing a CMOS of a semiconductor device.

Referring to FIG. 7, the electrostatic discharge element 1100 includes a first diode and a second diode. The first diode includes a P-type well region 1110a formed in a substrate 1105, N-type ion-implanted regions 1120 formed in the P-type well region 1110a and spaced from each other by a predetermined distance d3, a first intermediate layer 1150a formed on a portion of the P-type well region 1110a corresponding to the predetermined distance d3, and isolation regions 1160 formed outside the N-type ion-implanted regions 1120. The second diode includes an N-type well region 1110b formed in the P-type well region 1110a, P-type ion-implanted regions 1130 formed in the N-type well region 1110b and spaced from each other by a predetermined distance d4, a second intermediate layer 1150b formed on a portion of the N-type well region 1110b corresponding to the predetermined distance d4, and isolation regions 1160 formed outside the P-type ion-implanted regions 1130.

The first intermediate layer 1150a includes a first insulating layer 1140a and a first conductive layer 1145a. The second intermediate layer 1150b includes a second insulating layer 1140b and a second conductive layer 1145b. Each of the first and the second insulating layers can be made of silicon oxide, and each of the first and the second conductive layers can be made of any one of poly silicon, metal containing silicon, and metal, as examples.

Each of the isolation regions 1160 can be an STI (Shallow Trench Isolation), for example.

Although the widths of the intermediate layers 1150a and 1150b are the same as the distances d3 and d4 in FIG. 7, the widths of the intermediate layers can be larger than the distances d3 and d4.

In various embodiments, the isolation regions 1160 can be omitted, and are selectively included and formed according to a user's needs or the requirements of the semiconductor device.

In various embodiment, the N-type well region 1110b need not be formed in the P-type well region 1110a, and can be formed independently of the P-type well region 1110a. In addition, as an alterative approach, the P-type well region 1110a can be formed in the N-type well region 1110b.

A size and shape of each component has been simplified and exaggerated to more easily describe the embodiments and aspects of the invention. For instance, the electrostatic discharge element need not be formed in a rectangular shape, but could alternatively be formed in a round shape, for example.

As shown in FIG. 7, one N-type ion-implanted region 1120 can be electrically connected to an input/output node I/O, and the other N-type ion-implanted region 1120 can be electrically connected to a ground voltage node Vss. The first conductive layer 1145a can be electrically connected to one of the N-type ion-implanted regions 1120.

As is also shown in FIG. 7, one P-type ion-implanted region 1130 can be electrically connected to an input/output node I/O, and the other P-type ion-implanted region 1130 can be electrically connected to a power supply voltage node Vdd. The second conductive layer 1145b can be electrically connected to one of the P-type ion-implanted regions 1130.

In the embodiment of FIG. 7, the electrostatic discharge element 1100 has excellent performance in electrostatic discharge.

In addition, since the electrostatic discharge element 1100 can be manufactured using the same process as a process of manufacturing a CMOS, it is possible to easily manufacture the electrostatic discharge element 1100 without special processes.

As described above, since the electrostatic discharge element according to the various embodiments of the invention can be manufactured using an existing manufacturing process, it is possible to easily manufacture the electrostatic discharge. Furthermore, since the electrostatic discharge element has low electrical resistance when being turned on, the electrostatic discharge element has excellent performance in electrostatic discharge.

While the foregoing has described what are considered to be the best mode and/or other preferred embodiments, it will be apparent to those skilled in the art that various modifications and changes can be made thereto without departing from the scope and spirit of the invention. Therefore, it should be understood that the above embodiments are not limitative, but illustrative in all aspects. It is intended by the following claims to claim that which is literally described and all equivalents thereto, including all modifications and variations that fall within the scope of each claim.

What is claimed is:

1. An electrostatic discharge element comprising:
a first diode including a first well region formed in a substrate, a P-type ion-implanted region formed in the first well region, an N-type ion-implanted region formed in the first well region and spaced from the P-type ion-implanted region by a predetermined first distance, and a first intermediate layer formed on a portion of the first well region corresponding to the predetermined first distance; and
a second diode including a second well region form in the substrate, a P-type ion-implanted region formed in the second well region, an N-type ion-implanted region formed in the second well region and spaced from the P-type ion-implanted region by a predetermined second distance, and a second intermediate layer formed on a portion of the second well region corresponding to the predetermined second distance.

2. The electrostatic discharge element of claim 1, wherein the first intermediate layer includes a first insulating layer and a first conductive layer and the second intermediate layer includes a second insulating layer and a second conductive layer.

3. The electrostatic discharge element of claim 2, wherein each of the first and the second insulating layers comprises silicon oxide, and each of the first and the second conductive layers comprises at least one of poly silicon, metal containing silicon, and metal.

4. The electrostatic discharge element of claim 1, further comprising:
a ground voltage node electrically connected to the P-type ion-implanted region formed in the first well region;
a power supply voltage node electrically connected to the N-type ion-implanted region formed in the second well region; and
an input/output node electrically connected to the N-type ion-implanted region formed in the first well region and the P-type ion-implanted region formed in the second well region.

5. The electrostatic discharge element of claim 1, wherein the first well region is a P-type well region, and the second well region is an N-type well region.

6. The electrostatic discharge element of claim 1, further comprising a third intermediate layer formed between the first and second intermediate layers and between the P-type and N-type ion-implanted regions.

7. The electrostatic discharge element of claim 1, further comprising an isolation region formed between the P-type or N-type ion-implanted regions.

8. A method of manufacturing an electrostatic discharge element, the method comprising:
forming a first well region in a substrate;
forming a second well region in the substrate;
forming an intermediate layer on the first and the second well regions;
forming P-type ion-implanted regions in the first and the second well regions; and
forming N-type ion-implanted regions in the first and the second well regions.

9. The method of claim 8, wherein the first well region is a P-type well region, and the second well region is an N-type well region.

10. The method of claim 8, wherein the intermediate layer is formed by laminating together an insulating layer and a conductive layer.

11. The method of claim 10, wherein the insulating layer comprises silicon oxide, and the conductive layer comprises at least one of poly silicon, metal containing silicon, and metal.

12. A diode comprising:
a well region formed in a substrate;
a P-type ion-implanted region formed in the well region;
a N-type ion-implanted region formed in the well region and spaced from the P-type ion-implanted region by a predetermined distance; and
an intermediate layer formed on a portion of the well region corresponding to the predetermined distance between the P-type ion-implanted region and the N-type ion-implanted region.

13. The diode of claim 12, wherein a width of the first intermediate layer is larger than the distance.

14. The diode of claim 12, further comprising a second intermediate layer formed on the substrate with one of the P-type or N-type ion-implanted regions between the second intermediate layer and the first intermediate layerintermediate.

15. The diode of claim 12, further comprising an isolation region formed between the P-type or N-type ion-implanted regions.

16. The diode of claim 12, further comprising an isolation region formed in the substrate and configured to surround the P-type ion-implanted region, the N-type ion-implanted region, and the first intermediate layer in three or more directions.

17. A diode comprising:
a well region formed in a substrate;
a first ion-implanted region formed in the well region;
a second ion-implanted region formed in the well region and spaced from the first ion-implanted region by a first distance in one direction;
a third ion-implanted region formed in the well region and spaced from the first ion-implanted region by a second distance in another direction opposite to the one direction;
a first insulating layer formed on a portion of the well region corresponding to the first distance;
a first conductive layer formed on the first insulating layer;
a second insulating layer formed on a portion of the well region corresponding to the second distance; and
a second conductive layer formed on the second insulating layer.

18. A diode comprising:
a well region formed in a substrate;
a first ion-implanted region formed in the well region;
an insulating layer formed in the well region and configured to surround the first ion-implanted region in three directions;
a conductive layer formed on the insulating layer; and
a second ion-implanted region formed in the well region and outside the insulating layer.

19. A diode comprising:
a well region formed in a substrate;
a first ion-implanted region formed in the well region;
an insulating layer formed in the well region and configured to surround the first ion-implanted region in four directions;
a conductive layer formed on the insulating layer; and
a second ion-implanted region formed in the well region and outside the insulating layer.

20. An electrostatic discharge element comprising:
a first diode comprising a P-type well region formed in a substrate, N-type ion-implanted regions formed in the P-type well region and spaced from each other by a predetermined first distance, a first intermediate layer formed on a portion of the well region corresponding to the predetermined first distance, and isolation regions formed outside the N-type ion-implanted regions; and
a second diode comprising a N-type well region formed in the P-type well region, P-type ion-implanted regions formed in the N-type well region and spaced from each other by a predetermined second distance, a second intermediate layer formed on portion of the well region corresponding to the predetermined second distance, and isolation regions formed outside the P-type ion-implanted regions.
